(19) United States
(12) Patent Application Publication
(10) Pub. No.: US 2024/0324287 A1
(43) Pub. Date: Sep. 26, 2024

(54) DISPLAY DEVICE

(71) Applicant: Samsung Display Co., Ltd., Yongin-si (KR)

(72) Inventors: Donghee Shin, Yongin-si (KR); Sangyong No, Yongin-si (KR); Sunkwun Son, Yongin-si (KR)

(21) Appl. No.: 18/527,096

(22) Filed: Dec. 1, 2023

(30) Foreign Application Priority Data
Mar. 24, 2023 (KR) 10-2023-0039211
Jun. 15, 2023 (KR) 10-2023-0077061

(51) Int. Cl. H10K 59/121; H10K 59/131

(52) U.S. Cl. CPC H10K 59/1213; H10K 59/131

(57) ABSTRACT

A display device includes a substrate including a display area in which display elements are arranged, a first subpixel circuit unit in the display area and including a first subpixel circuit, a second subpixel circuit, and a third subpixel circuit, a first scan line extending in a first direction from a side of the first subpixel circuit unit, a second scan line extending in the first direction from another side of the first subpixel circuit unit, a first branch line extending from the first scan line in a second direction crossing the first direction, and a first compensation line extending in the first direction from the first branch line toward the first subpixel circuit adjacent to the second scan line.

### CROSS-REFERENCE TO RELATED APPLICATIONS

The present application claims priority to and the benefit of Korean Patent Application No. 10-2023-0039211, filed on Mar. 24, 2023, and Korean Patent Application No. 10-2023-0077061, filed on Jun. 15, 2023, in the Korean Intellectual Property Office, the entire contents of which are incorporated by reference herein.

### BACKGROUND

### 1. Field

Aspects of preset disclosure are related to a display device.

### 2. Description of Related Art

Display devices display data in a visual manner. Display devices may be configured to provide images using light-emitting diodes. Display devices have been used for various purposes, and numerous designs to improve the quality of display devices have been attempted.

### SUMMARY

Aspects of some embodiments are directed to a display device with improved reliability and quality. However, this is only an example, and the technical goals of the embodiments are not limited thereto.

Additional aspects will be set forth in part in the description which follows and, in part, will be apparent from the description, or may be learned by practice of the presented embodiments of the disclosure.

According to some embodiments of the present disclosure, there is provided a display device including: a substrate including a display area in which display elements are arranged; a first subpixel circuit unit in the display area and including a first subpixel circuit, a second subpixel circuit, and a third subpixel circuit; a first scan line extending in a first direction from a side of the first subpixel circuit unit; a second scan line extending in the first direction from another side of the first subpixel circuit unit; a first branch line extending from the first scan line in a second direction crossing the first direction; and a first compensation line extending in the first direction from the first branch line toward the first subpixel circuit adjacent to the second scan line.

In some embodiments, the first subpixel circuit includes: a first thin-film transistor in the display area and including a first semiconductor layer and a first gate electrode insulated from the first semiconductor layer; and a second thin-film transistor in the display area and including a second semiconductor layer and a second gate electrode insulated from the second semiconductor layer.

In some embodiments, a minimum distance in the second direction between the first thin-film transistor and the second scan line is less than a minimum distance in the second direction between the second thin-film transistor and the second scan line.

In some embodiments, the first subpixel circuit is adjacent to the second scan line, the third subpixel circuit is adjacent to the first scan line, and the second subpixel circuit is between the first subpixel circuit and the third subpixel circuit.

In some embodiments, at least a portion of the first branch line is integrally formed in the first gate electrode of the first thin-film transistor.

In some embodiments, at least a portion of the first branch line is integrally formed in the second gate electrode of the second thin-film transistor.

In some embodiments, the first compensation line is at a same layer as the first branch line and includes a same material as a material of the first branch line.

In some embodiments, the first compensation line is between the second scan line and the first thin-film transistor and extends in the first direction from the first branch line.

In some embodiments, the first compensation line is between the first thin-film transistor and the second thin-film transistor and extends in the first direction from the first branch line.

In some embodiments, the display device further includes a second compensation line extending in the first direction from the first branch line toward the second subpixel circuit.

In some embodiments, the second compensation line is at a same layer as the first branch line and includes a same material as a material of the first branch line.

According to some embodiments of the present disclosure, there is provided a display device including: a substrate including a display area in which display elements are arranged; a second subpixel circuit unit in the display area and including a first subpixel circuit, a second subpixel circuit, and a third subpixel circuit; a first scan line extending in a first direction from a side of the second subpixel circuit unit; a second scan line extending in the first direction from another side of the second subpixel circuit unit; a second branch line extending from the second scan line in a second direction crossing the first direction; and a third compensation line extending in the first direction from the second branch line toward the third subpixel circuit adjacent to the first scan line.

In some embodiments, the third subpixel circuit includes: a third thin-film transistor in the display area and including a third semiconductor layer and a third gate electrode insulated from the third semiconductor layer; and a fourth thin-film transistor in the display area and including a fourth semiconductor layer and a fourth gate electrode insulated from the fourth semiconductor layer.

In some embodiments, a minimum distance in the second direction between the third thin-film transistor and the first scan line is less than a minimum distance in the second direction between the fourth thin-film transistor and the first scan line.

In some embodiments, the second branch line is integrally formed in the third gate electrode of the third thin-film transistor.

In some embodiments, the second branch line is integrally formed in the fourth gate electrode of the fourth thin-film transistor.

In some embodiments, the third compensation line is at a same layer as the second branch line and includes a same material as a material of the second branch line.

In some embodiments, the third compensation line is between the first scan line and the third thin-film transistor and extends in the first direction from the second branch line.

In some embodiments, the third compensation line is between the third thin-film transistor and the fourth thin-film transistor and extends in the first direction from the second branch line.

In some embodiments, the display device further includes a fourth compensation line extending in the first direction from the second branch line toward the second subpixel circuit.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 and 2 are perspective views each schematically illustrating a display device according to some embodiments of the present disclosure;

FIG. 3 is an equivalent circuit diagram schematically illustrating any one subpixel circuit provided in a display device according to some embodiments of the present disclosure;

FIG. 4 is a cross-sectional view schematically illustrating a display device according to some embodiments of the present disclosure;

FIG. 5 is a top-plan view schematically illustrating subpixels provided in a display device according to some embodiments of the present disclosure;

FIGS. 6 and 7 are top-plan views schematically illustrating subpixel circuits provided in a display device according to some embodiments of the present disclosure; and

FIGS. 8 and 9 are top-plan views schematically illustrating subpixel circuits provided in a display device according to some embodiments of the present disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, a specific quantity or range recited in this written description or the claims may also encompass the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The display device and/or any other relevant devices or components according to embodiments of the present invention described herein may be implemented utilizing any suitable hardware, firmware (e.g., an application-specific integrated circuit), software, or a suitable combination of software, firmware, and hardware. For example, the various components of the display device may be formed on one integrated circuit (IC) chip or on separate IC chips. Further, the various components of the display device may be implemented on a flexible printed circuit film, a tape carrier package (TCP), a printed circuit board (PCB), or formed on a same substrate. Further, the various components of the display device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention.

In the drawings, the sizes of elements may be exaggerated or reduced for convenience of description. For example, since the size and thickness of each element is arbitrarily shown in the drawings for convenience of description, the disclosure is not necessarily limited to those illustrated.

When some embodiments may be differently implemented, a particular process sequence may be performed differently from a sequence described. For example, two processes described in succession may be performed substantially simultaneously, or may be performed in an order opposite to an order described.

In the present specification, when it is referred that a film, an area, and a component are connected to another film, area, and component, the film, area, and component may be directly connected to the other film, area, and component, or may be indirectly connected with another film, area, and component therebetween. For example, when it is referred that a film, an area, and a component are electrically connected to another film, area, and component, the film, area, and component may be directly in electric connection with the other film, area, and component, or may be indirectly in electric connection with the other film, area, and component with another film, area, and component therebetween.

An x-axis, a y-axis, and a z-axis are not limited to three axes on an orthogonal coordinate system, and may be interpreted as a wide meaning including the same. For example, the x-axis, y-axis, and z-axis may be orthogonal to one another, but may also refer to different directions that are not orthogonal to one another.

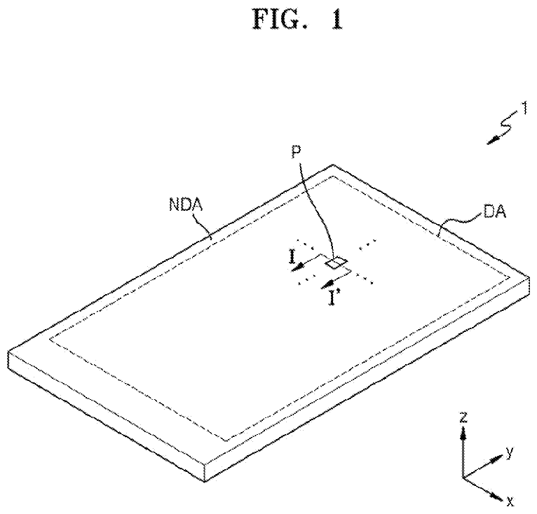

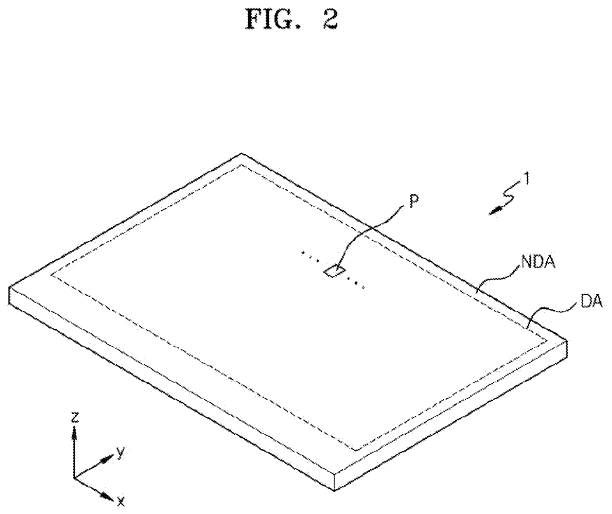

FIGS. 1 and 2 are cross-sectional views each schematically illustrating a display device 1 according to some embodiments of the present disclosure.

Referring to FIGS. 1 and 2, the display device 1 may include a display area DA and a non-display area NDA located outside the display device DA. The display area DA may be configured to display images through subpixels P arranged in the display area DA. The non-display area NDA, which is an area arranged outside the display area DA and does not display images, may entirely surround the display area DA. A driver configured to provide electrical signals or power to the display area DA may be arranged in the non-display area NDA. A pad, which is an element to which electrical devices or a printed circuit board may be electrically connected, may be arranged in the non-display area NDA.

In some embodiments, FIG. 1 illustrates that the display area DA has a polygon shape (e.g., a square) in which a length in an x direction is less than a length in a y direction. However, in some other embodiments, FIG. 2 illustrates that the display area DA has a polygon shape (e.g., a square shape) in which the length in the y direction is less than the length in the x direction. Although FIGS. 1 and 2 illustrate that the display area DA has an approximately square shape, the embodiments of the present disclosure are not limited thereto. In some other examples, the display area DA may have various suitable shapes such as an N-side shape (where N is a natural number equal to or greater than three), a circle, an oval, or the like. Although FIGS. 1 and 2 illustrate that the display area DA has a shape in which a corner portion of the display area DA includes a vertex at which two straight lines meet each other, in some other examples, the display area DA may have a polygon shape having rounded corner portions.

Hereinafter, for convenience of explanation, a case in which the display device 1 includes an electronic device, for example, a smart phone, will be described, but the display device 1 according to embodiments is not limited thereto. For example, the display device 1 may be applied to various products such as televisions, notebooks, monitors, billboard charts, Internet of things (IoT) devices, and the like, as well as mobile electronic devices such as mobile phones, smart phones, tablet personal computers, mobile communication terminals, electronic handbooks, electronic books, portable multimedia players, navigation systems, ultra mobile PCs. In addition, the display device 1 according to some embodiments is used for wearable devices such as smart watches, watch phones, and head mounted displays (HMD). The display device 1 according to some examples may include a center information display (CID) arranged on a dashboard or a center fascia of a vehicle, may include a room mirror display substituting a side mirror of a vehicle, and may be used as a display screen arranged on a back surface of a front seat as entertainment for passengers in rear seats of a vehicle.

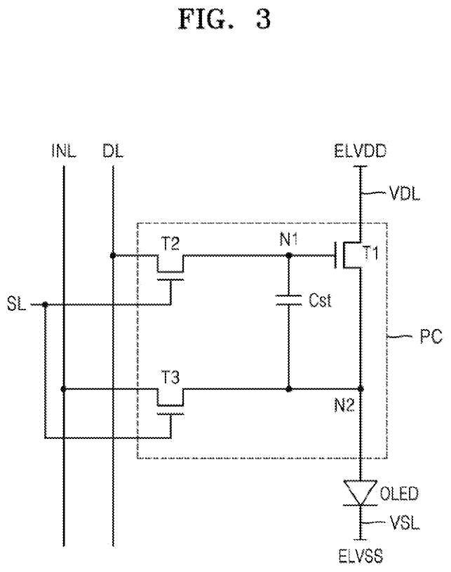

FIG. 3 is an equivalent circuit diagram schematically illustrating any one subpixel PC provided in the display device 1 according to some embodiments of the present disclosure.

Referring to FIG. 3, the subpixel circuit PC may include a plurality of thin-film transistors and at least one capacitor. In some embodiments, the subpixel circuit PC includes a first thin-film transistor T1, a second thin-film transistor T2, a third thin-film transistor T3, and a storage capacitor Cst.

Each of the first thin-film transistor T1, the second thin-film transistor T2, and the third thin-film transistor T3 may include an oxide semiconductor thin-film transistor including a semiconductor layer including an oxide semiconductor or a silicon semiconductor thin-film transistor including a semiconductor layer including polysilicon. Each of the first thin-film transistor T1, the second thin-film transistor T2, and the third thin-film transistor T3 may include a first electrode and a second electrode, and according to a type of the thin-film transistor, the first electrode may include one of a source electrode and a drain electrode, and the second electrode may include another one of the source electrode and the drain electrode. In addition, each of the first thin-film transistor T1, the second thin-film transistor T2, and the third thin-film transistor may include a gate electrode.

The first thin-film transistor T1 may include a driving thin-film transistor. The first electrode of the first thin-film transistor T1 may be connected to a driving voltage line VDL configured to provide a driving power voltage ELVDD, and a second electrode of the first thin-film transistor T1 may be connected to a pixel electrode of an organic light-emitting diode OLED. The gate electrode of the first thin-film transistor T1 may be connected to a first node N1. The first thin-film transistor T1 may be configured to control an amount of power (e.g., amount of current) flowing through the organic light-emitting diode OLED from the driving power voltage ELVDD, in response to a voltage of the first node N1.

The second thin-film transistor T2 may include a switching thin-film transistor. A first electrode of the second thin-film transistor T2 may be connected to a data line DL, and a second electrode of the second thin-film transistor T2 may be connected to the first node N1. A gate electrode of the second thin-film transistor T2 may be connected to a scan line SL. The second thin-film transistor T2 may be turned on when a scan signal is provided from the scan line SL and may electrically connect the data line DL and the first node N1.

The third thin-film transistor T3 may include an initialization thin-film transistor and/or a sensing thin-film transistor. A first electrode of the third thin-film transistor T3 may be connected to a second node N2, and a second electrode of the third thin-film transistor T3 may be connected to an initialization voltage line INL. A gate electrode of the third thin-film transistor T3 may be connected to the scan line SL.

The third thin-film transistor T3 may be turned on when the scan signal is provided from the scan line SL and may electrically connect the initialization voltage line INL and the second node N2. In some embodiments, the third thin-film transistor T3 is turned on in response to a signal delivered through the scan line SL and may initialize the pixel electrode of the organic light-emitting diode OLED using an initialization voltage from the initialization voltage line INL.

In some embodiments, the third thin-film transistor T3 is turned on when the scan signal is provided from the scan line SL and may sense characteristic information of the organic light-emitting diode OLED. The third thin-film transistor T3 may have all or any one of a function as the initialization thin-film transistor or a function of the sensing thin-film transistor. An initialization operation and a sensing operation of the third thin-film transistor T3 may be separately or concurrently (e.g., simultaneously) performed. When the third thin-film transistor T3 has the function as the sensing thin-film transistor, the initialization voltage line INL may be referred to as a sensing line.

The storage capacitor Cst may be connected between the first node N1 and the second node N2. For example, a first capacitor plate (e.g., a first capacitor electrode) of the storage capacitor Cst may be connected to the gate electrode of the first thin-film transistor T1, and a second capacitor plate (e.g., a second capacitor electrode) of the storage capacitor Cst may be connected to the pixel electrode of the organic light-emitting diode OLED.

A counter electrode of the organic light-emitting diode OLED may be connected to a common voltage line configured to provide a common power voltage ELVSS.

Although FIG. 3 illustrates that the subpixel circuit PC includes three thin-film transistors and one storage capacitor, the embodiments of the present disclosure are not limited thereto. In some other embodiments, the number of thin-film transistors or the number of storage capacitor may be variously modified in a suitable manner according to the design of the subpixel circuit PC.

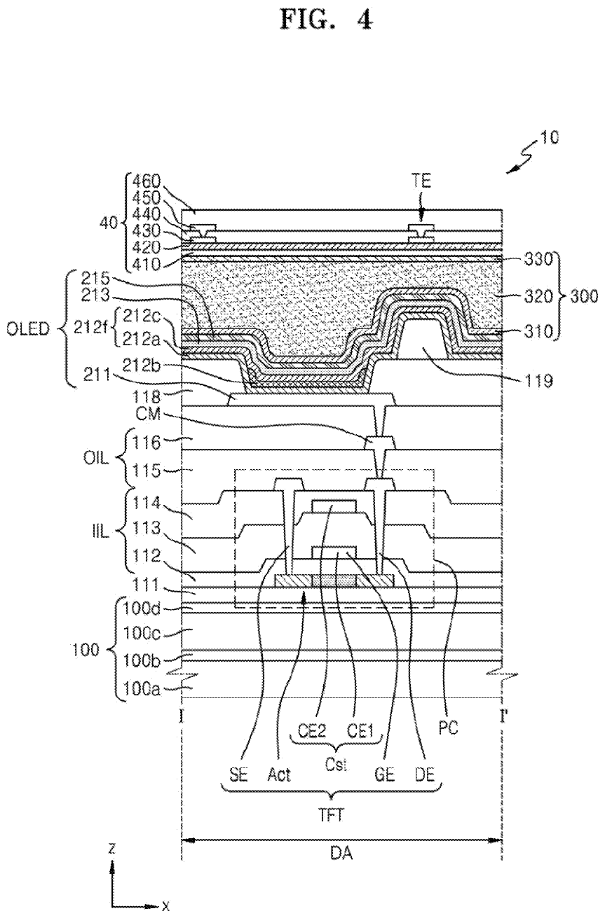

FIG. 4 is a cross-sectional view schematically illustrating the display device 1 according to some embodiments of the present disclosure. More particularly, FIG. 4 is a cross-sectional view schematically illustrating the display device 1 taken along the line I-I′ of FIG. 1.

Referring to FIG. 4, a display panel 10 may include a substrate 100, an inorganic insulating layer IIL, an organic insulating layer OIL, the subpixel circuit PC, a connection electrode CM, the organic light-emitting diode OLED, a pixel defining film 118, a spacer 119, and an encapsulation layer 300. That is, the substrate 100, the inorganic insulating layer IIL, the organic insulating layer OIL, the subpixel circuit PC, the connection electrode CM, the organic light-emitting diode OLED, the pixel defining film 118, the spacer 119, and the encapsulation layer 300 may be arranged in the display area DA of the display panel 10.

The substrate 100 may include a first base layer 100a, a first barrier layer 100b, a second base layer 100c, and a second barrier layer 100d. In some embodiments, the first base layer 100a, the first barrier layer 100b, the second base layer 100c, and the second barrier layer 100d are sequentially stacked in a direction of a thickness of the substrate 100 (e.g., along the z axis).

At least one of the first base layer 100a and the second base layer 100c may include a polymer resin such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like.

The first barrier layer 100b and the second barrier layer 100d, which are barrier layers preventing or substantially reducing permeation of foreign impurities, may each include a single layer or multiple layers including an inorganic material such as silicon nitride (SiNₓ), silicon oxide (SiO₂), silicon oxynitride (SiON), or the like.

A buffer layer 111 may be disposed on the substrate 100. The buffer layer 111 may include an inorganic insulating material such as SiNₓ, SiON, SiO₂, or the like and may include a single layer or multiple layers including the aforementioned inorganic insulating materials.

The inorganic insulating layer IIL may be disposed on the buffer layer 111. The inorganic insulating layer IIL may include a first gate insulating layer 112, a second gate insulating layer 113, and an interlayer insulating layer 114.

The subpixel circuit PC may be arranged in the display area DA. The subpixel circuit PC may include a thin-film transistor TFT and the storage capacitor Cst. The thin-film transistor TFT may include a semiconductor layer Act, a gate electrode GE, a source electrode SE, and a drain electrode DE.

The semiconductor layer Act may be disposed on the buffer layer 111. The semiconductor layer Act may include polysilicon and/or the like. In some examples, the semiconductor layer Act may include amorphous silicon, an oxide semiconductor, an organic semiconductor, and the like. The semiconductor layer Act may include a channel area, and may also include a drain area and a source area arranged at two sides (e.g., opposite sides) of the channel area.

The gate electrode GE may be disposed above the semiconductor layer Act. The gate electrode GE may overlap the channel area. The gate electrode GE may include a low-resistant metal material. The gate electrode GE may include a conductive material including molybdenum (Mo), aluminum (Al), copper (Cu), titanium (Ti), and/or the like, and may include multiple layers or a single layer including the aforementioned materials.

The first gate insulating layer 112 may be disposed between the semiconductor layer Act and the gate electrode GE. The first gate insulating layer 112 may include an inorganic insulating material such as SiO₂, SiNₓ, SiON, aluminum oxide (Al₂O₃), titanium oxide (TiO₂), tantalum oxide (Ta₂O₅), hafnium oxide (HfO₂), zinc oxide (ZnO), or the like.

The second gate insulating layer 113 may be disposed on the gate electrode GE. The second gate insulating layer 113 may be provided to cover the gate electrode GE. The second gate insulating layer 113 may include an inorganic insulating material such as SiO₂, SiNₓ, SiON, Al₂O₃, TiO₂, Ta₂O₅, HfO₂, ZnO, or the like.

A second capacitor plate (e.g., a second capacitor electrode) CE2 of the storage capacitor Cst may be disposed on the second gate insulating layer 113. The second capacitor plate CE2 may overlap the gate electrode GE disposed thereunder. In this case, the gate electrode GE and the second capacitor plate CE2 overlapping each other with the second gate insulating layer 113 therebetween may form the storage capacitor Cst. That is, the gate electrode GE may function as the first capacitor plate (e.g., the first capacitor electrode) CE1 of the storage capacitor Cst.

Like this, the storage capacitor Cst and the thin-film transistor TFT may be formed in an overlapping manner. However, the embodiments of the present disclosure are not limited thereto. For example, the storage capacitor Cst may be formed to not overlap the thin-film transistor TFT. That is, the first capacitor plate CE1 of the storage capacitor Cst may be a component separate from the gate electrode GE of the thin-film transistor TFT, and may be provided apart from the gate electrode GE of the thin-film transistor TFT.

The second capacitor plate CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), and/or the like, and may include a single layer or multiple layers including the aforementioned materials.

The interlayer insulating layer 114 may be disposed on the second capacitor plate CE2. The interlayer insulating layer 114 may cover the second capacitor plate CE2. The interlayer insulating layer 114 may include SiO₂, SiNₓ, SION, Al₂O₃, TiO₂, Ta₂O₅, HfO₂, ZnO, and/or the like. The interlayer insulating layer 114 may include a single layer or multiple layers including the aforementioned inorganic insulating materials.

Each of the drain electrode DE and the source electrode SE may be disposed on the interlayer insulating layer 114. The drain electrode DE and the source electrode SE may each be connected to the semiconductor layer Act through a contact hole provided in the first gate insulating layer 112, the second gate insulating layer 113, and the interlayer insulating layer 114. The drain electrode DE and the source electrode SE may include highly conductive materials. The drain electrode DE and the source electrode SE may include a conductive material including Mo, Al, Cu, and/or the like, and may each include multiple layers or a single layer including the aforementioned materials. For example, the drain electrode DE and the source electrode SE may each have a multi-layer structure including Ti/Al/Ti.

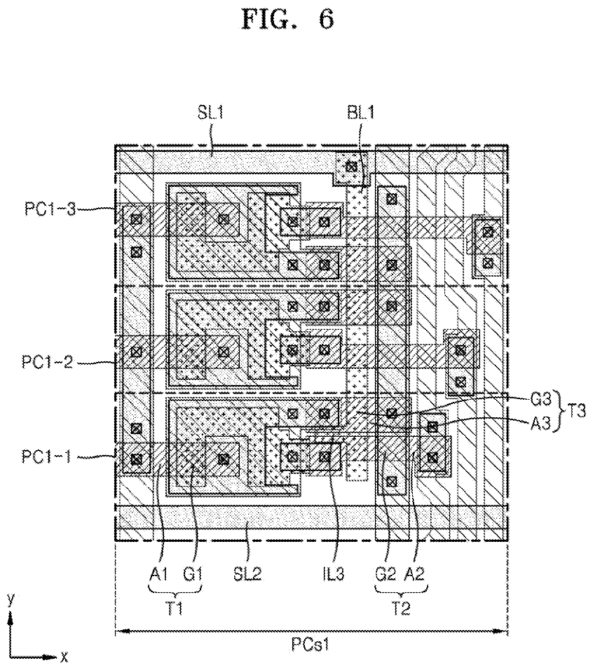

The organic insulating layer OIL may be disposed on the inorganic insulating layer IIL. The organic insulating layer OIL may include a first organic insulating layer 115 and a second organic insulating layer 116. Although FIG. 6 illustrates that the organic insulating layer OIL is provided as two organic insulating layers, the embodiments of the present disclosure are not limited thereto. The organic insulating layer OIL may also be provided as three or four organic insulating layers.

The first organic insulating layer 115 may cover the drain electrode DE and the source electrode SE. The first organic insulating layer 115 may include an organic insulating material, for example, a general-purpose polymer such as polymethylmethacrylate (PMMA) or polystyrene (PS), a polymer derivative having a phenol-based group, an acryl-based polymer, an imide-based polymer, an arylether-based polymer, an amide-based polymer, a fluoride-based polymer, a p-xylene based polymer, a vinylalcohol-based polymer, or blends thereof.

The connection electrode CM may be disposed on the first organic insulating layer 115. In this case, the connection electrode CM may be connected to the drain electrode DE or the source electrode SE through the contact hole in the first organic insulating layer 115. The connection electrode CM may include a highly conductive material. The connection electrode CM may include a conductive material including Mo, Al, Cu, Ti, and/or the like, and may include multiple layers or a single layer including the aforementioned materials. For example, the connection electrode CM may have a multi-layer structure including Tli/Al/Ti.

The second organic insulating layer 116 may be disposed on the connection electrode CM. The second organic insulating layer 116 may cover the connection electrode CM. The second organic insulating layer 116 may include a material identical to or different from a material of the first organic insulating layer 115.

A light-emitting diode may be disposed on the second organic insulating layer 116. For example, the organic light-emitting diode OLED may be disposed on the second organic insulating layer 116. In some examples, an inorganic light-emitting diode and the like may be disposed on the second organic insulating layer 116.

The organic light-emitting diode OLED may be configured to emit red, green, or blue light or emit red, green, blue, or white light. The organic light-emitting diode OLED may include a first electrode 211, an emission layer 212b, a function layer 212f, a second electrode 213, and a capping layer 215. The first electrode 211 may include a pixel electrode (e.g., an anode) of the organic light-emitting diode OLED, and the second electrode 213 may include a counter electrode (e.g., a cathode) of the organic light-emitting diode OLED.

The first electrode 211 may be disposed on the second organic insulating layer 116. The first electrode 211 may be electrically connected to the connection electrode CM through a contact hole defined in the second organic insulating layer 116. The first electrode 211 may include a conductive material such as indium tin oxide (ITO), indium zinc oxide (IZO), zinc oxide (ZnO), indium oxide (In₂O₃), indium gallium oxide (IGO), aluminum zinc oxide (AZO), or the like. In some embodiments, the first electrode 211 includes a reflective film including silver (Ag), magnesium (Mg), aluminum (Al), platinum (Pt), palladium (Pd), gold (Au), nickel (Ni), neodymium (Nd), iridium (Ir), chromium (Cr), or compounds thereof. In some embodiments, the first electrode 211 further includes a film including ITO, IZO, ZnO, In₂O₃, and/or the like, on/under the aforementioned reflective film. For example, the first electrode 211 may have a multi-layer structure including ITO/Ag/ITO.

A pixel defining film 118, in which an opening exposing at least a portion of the first electrode 211 is defined, may be disposed on the first electrode 211. An emission area of light emitted from the organic light-emitting diode OLED may be defined by the opening defined in the pixel defining film 118. For example, a width of the opening may correspond to a width of the emission area.

The pixel defining film 118 may include an organic insulating material. In some examples, the pixel defining film 118 may include an inorganic insulating material such as SiNₓ, SiON, SIO₂, or the like. In some examples, the pixel defining film 118 may include an organic insulating material and an inorganic insulating material. In some embodiments, the pixel defining film 118 includes a light-shielding material. The light-shielding material may include a resin or paste including carbon black, a carbon nanotube, or a black dye, metal particles such as Ni, Al, Mo, and alloys thereof, metal oxide particles (e.g., chromium oxide), or metal nitride particles (e.g., chromium nitride). When the pixel defining film 118 includes the light-shielding material, reflection of external light due to metal structures disposed under the pixel defining film 118 may be reduced.

The spacer 119 may be disposed on the pixel defining film 118. The spacer 119 may include an organic insulating material such as a polyimide, or the like. In some examples, the spacer 119 may include an inorganic insulating material such as SiNₓ, SiO₂, or the like or may include an organic insulating material and an inorganic insulating material.

In some embodiments, the spacer 119 includes a material identical to or substantially the same as a material of the pixel defining film 118. In this case, the pixel defining film 118 and the spacer 119 may be formed together in a mask process using a halftone mask and the like. In some examples, the spacer 119 and the pixel defining film 118 may respectively include different materials.

The emission layer 212b may be arranged in the opening of the pixel defining film 118. The emission layer 212b may include a high-molecular or low-molecular organic material emitting light having certain colors.

The function layer 212f may include a first function layer 212a and a second function layer 212c. The first function layer 212a may be disposed between the first electrode 211 and the emission layer 212b, and the second function layer 212c may be disposed between the emission layer 212b and the second electrode 213. However, at least one of the first function layer 212a and the second function layer 212c may be omitted. Hereinafter, a case in which the first function layer 212a and the second function layer 212c are respectively arranged will be mainly described in detail.

The first function layer 212a may include a hole transport layer (HTL) or a hole injection layer (HIL). The second function layer 212c may include an electron transport layer (ETL) and/or an electron injection layer (EIL). The first function layer 212a and/or the second function layer 212c may include a common layer formed to generally cover the substrate 100, like the second electrode 213 to be described below.

The second electrode 213 may be disposed on the function layer 212f. The second electrode 213 may include a conductive material having a small work function. For example, the second electrode 213 may include a (semi) transparent layer including Au, Mg, Al, Pt, Pd, Au, Ni, Nd, Ir, Cr, Li, Ca, or alloys thereof. In some examples, the second electrode 213 may further include a layer including ITO, IZO, ZnO, In₂O₃, or the like on the (semi) transparent layer including the aforementioned materials.

In some embodiments, the capping layer 215 is disposed on the second electrode 213. The capping layer 215 may include LiF, an inorganic material, and/or an organic material.

The encapsulation layer 300 may be disposed on the organic light-emitting diode OLED. The encapsulation layer 300 may cover the organic light-emitting diode OLED. The encapsulation layer 300 may be disposed on the second electrode 213 and/or the capping layer 215. In some embodiments, the encapsulation layer 300 includes at least one inorganic film layer and at least one organic film layer. FIG. 4 illustrates that the encapsulation layer 300 includes a first inorganic film layer 310, an organic film layer 320, and a second inorganic film layer 330 sequentially stacked.

The first inorganic film layer 310 and the second inorganic film layer 330 may include at least one inorganic material from among aluminum oxide, titanium oxide, tantalum oxide, hafnium oxide, zinc oxide, silicon oxide, silicon nitride, and silicon oxynitride. The first inorganic film layer 310 and the second inorganic film layer 330 may include a single layer or multiple layers including the aforementioned materials. The organic film layer 320 may include a polymer-based material. The polymer-based material may include an acryl-based resin, an epoxy-based resin, polyimide, polyethylene, and/or the like. In some embodiment, the organic film layer 320 includes acrylate and/or the like.

An input sensing layer 40 may be disposed on the encapsulation layer 300. The input sensing layer 40 may include a first touch insulating layer 410, a second touch insulating layer 420, a first conductive layer 430, a third touch insulating layer 440, a second conductive layer 450, and a planarization layer 460.

In some embodiments, the first touch insulating layer 410 is disposed on the second inorganic film layer 330, and the second touch insulating layer 420 is disposed on the first touch insulating layer 410. In some embodiments, the first touch insulating layer 410 and the second touch insulating layer 420 may each include an inorganic insulating layer and/or an organic insulating layer. For example, the first touch insulating layer 410 and the second touch insulating layer 420 may include an inorganic insulating layer such as silicon oxide, silicon nitride, silicon oxynitride, or the like.

In some embodiments, at least one of the first touch insulating layer 410 and the second touch insulating layer 420 is omitted. For example, the first touch insulating layer 410 may be omitted. In this case, the second touch insulating layer 420 may be disposed above the second inorganic film layer 330, and the first conductive layer 430 may be disposed on the second touch insulating layer 420.

The first conductive layer 430 may be disposed on the second touch insulating layer 420, and the third touch insulating layer 440 may be disposed on the first conductive layer 430. In some embodiments, the third touch insulating layer 440 includes an inorganic insulating material and/or an organic insulating material. For example, the third touch insulating layer 440 may include an inorganic insulating material such as silicon oxide, silicon nitride, silicon oxynitride, and/or the like.

The second conductive layer 450 may be disposed on the third touch insulating layer 440. A touch electrode TE of the input sensing layer 40 may be provided as a structure in which the first conductive layer 430 and the second conductive layer 450 contact each other. In some examples, the touch electrode TE may be formed in any one of the first conductive layer 430 and the second conductive layer 450, and may include a metal line provided in a corresponding conductive layer. The first conductive layer 430 and the second conductive layer 450 may include at least one of aluminum (Al), copper (Cu), titanium (Ti), molybdenum (Mo), and indium tin oxide (ITO), and may each include a single layer or multiple layers including the aforementioned materials. For example, the first conductive layer 430 and the second conductive layer 450 may each have a three-layer structure including a titanium layer, an aluminum layer, and a titanium layer.

In some embodiments, the planarization layer 460 covers the second conductive layer 450. The planarization layer 460 may include an organic insulating material.

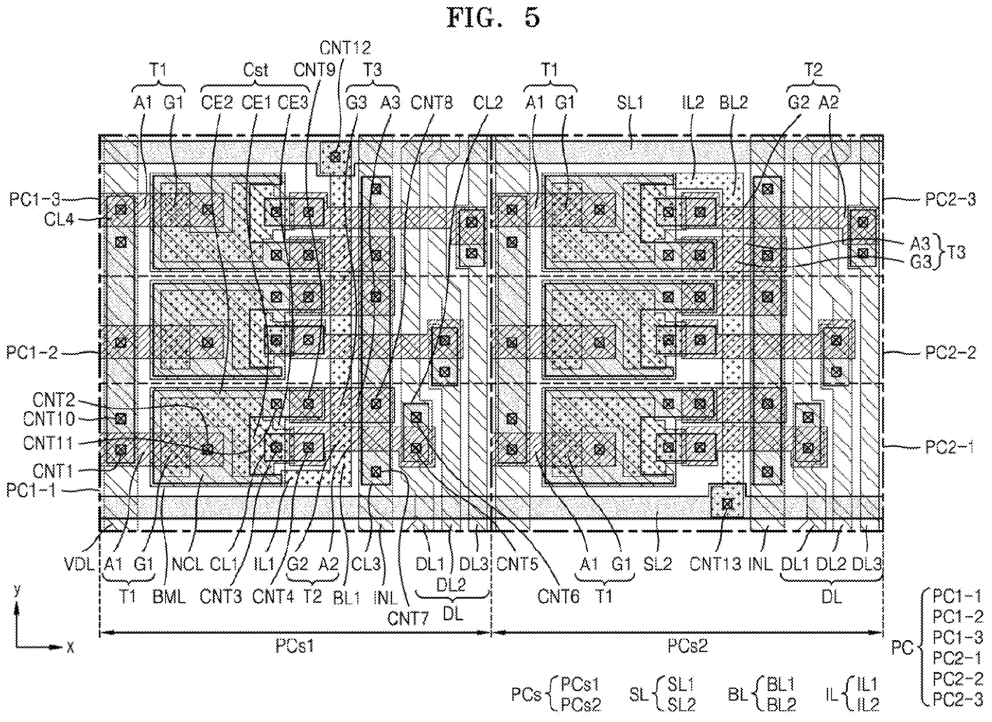

FIG. 5 is a top-plan view schematically illustrating subpixel circuits PCs provided in the display device 1 according to some embodiments of the present disclosure.

Referring to FIG. 5, the display device 1 may include a plurality of subpixel circuit units PCs. The plurality of subpixel circuit units PCs is shown as a first subpixel circuit unit PCs1 and a second subpixel circuit unit PCs2. The first subpixel circuit unit PCs1 may include a 1-1 subpixel circuit PC1-1, a 1-2 subpixel circuit PC1-2, and a 1-3 subpixel circuit PC1-3. The second subpixel circuit unit PCs2 may include a 2-1 subpixel circuit PC2-1, a 2-2 subpixel circuit PC2-2, and a 2-3 subpixel circuit PC2-3. In addition, the display device 1 may include various wirings electrically connected to the subpixel circuits PC, for example, the scan line SL, a plurality of data lines DL, branch lines BL, the initialization voltage line INL, the driving voltage line VDL, and compensation lines IL.

A first scan line SL1 and a second scan line SL2 may extend in a first direction (e.g., an x direction or −x direction). The plurality of data lines DL may extend in a second direction (e.g., a y direction or −y direction) crossing the first direction (e.g., the x direction or −x direction). The driving voltage line VDL and the initialization voltage line INL may extend in the second direction (e.g., the y direction or −y direction). A first branch line BL1 connected from the first scan line SL1 may extend in the second direction (e.g., the y direction or −y direction), and a first compensation line IL1 connected from the first branch line BL1 may extend in the first direction (e.g., the x direction or −x direction). A second branch line BL2 connected from the second scan line SL2 may extend in the second direction (e.g., the y direction or −y direction), and a second compensation line IL2 connected from the second branch line BL2 may extend in the first direction (e.g., the x direction or −x direction).

In some embodiments, the scan line SL includes the first scan line SL1 and the second scan line SL2. The first scan line SL1 and the second scan line SL2 may extend in the first direction (e.g., the x direction or −x direction). For example, the first scan line SL1 may extend in the first direction from a side of the first subpixel circuit unit PCs1. The second scan line SL2 may extend in the first direction (e.g., the x direction or −x direction) from another side of the first subpixel circuit unit PCs1. The first scan line SL1 and the second scan line SL2 may be arranged apart from each other in the second direction (e.g., the y direction or −y direction) with the first subpixel circuit unit PCs1 therebetween. The first scan line SL1 may be configured to provide a scan signal to the 1-1 subpixel circuit PC1-1, the 1-2 subpixel circuit PC1-2, and the 1-3 subpixel circuit PC1-3 of the first subpixel circuit unit PCs1. For example, the first scan line SL1 may be electrically connected to the first branch line BL1 extending in the second direction from the first scan line SL1 and provide the scan signal to the 1-1 subpixel circuit PC1-1, the 1-2 subpixel circuit PC1-2, and the 1-3 subpixel circuit PC1-3 of the first subpixel circuit unit PCs1.

In some embodiments, the first scan line SL1 extends in the first direction (e.g., the x direction or −x direction) from a side of the second subpixel circuit unit PCs2. The second scan line SL2 may extend in the first direction from another side of the second subpixel circuit unit PCs2. The first scan line SL1 and the second scan line SL2 may be arranged apart from each other in the second direction (e.g., the y direction or the −y direction) with the second subpixel circuit unit PCs2 therebetween. The second scan line SL2 may be configured to provide the scan signal to the 2-1 subpixel circuit PC2-1, the 2-2 subpixel circuit PC2-2, and the 2-3 subpixel circuit PC2-3 of the second subpixel circuit unit PCs2. For example, the second scan line SL2 may be electrically connected to the second branch line BL2 extending in the second direction from the second scan line SL2 and provide the scan signal to the 2-1 subpixel circuit PC2-1, the 2-2 subpixel circuit PC2-2, and the 2-3 subpixel circuit PC2-3 of the second subpixel circuit unit PCs2.

The 1-1 subpixel circuit PC1-1, the 1-2 subpixel circuit PC1-2, and the 1-3 subpixel circuit PC1-3 may be arranged in series in the second direction (e.g., the y direction or −y direction). For example, the 1-1 subpixel circuit PC1-1 may be arranged adjacent to the second scan line SL2, and the 1-3 subpixel circuit PC1-3 may be arranged adjacent to the first scan line SL1. The 1-2 subpixel circuit PC1-2 may be arranged between the 1-1 subpixel circuit PC1-1 and the 1-3 subpixel circuit PC1-3. In addition, the 2-1 subpixel circuit PC2-1, the 2-2 subpixel circuit PC2-2, and the 2-3 subpixel circuit PC2-3 may be arranged in series in the second direction. For example, the 2-1 subpixel circuit PC2-1 may be arranged adjacent to the second scan line SL2, and the 2-3 subpixel circuit PC2-3 may be arranged adjacent to the first scan line SL1. The 2-2 subpixel circuit PC2-2 may be arranged between the 2-1 subpixel circuit PC2-1 and the 2-3 subpixel circuit PC2-3.

The plurality of data lines DL may be arranged to extend in the second direction at a side of the first subpixel circuit unit PCs1. The plurality of data lines DL may be arranged to extend in the second direction at a side of the second subpixel circuit unit PCs2. The plurality of data lines DL may include, for example, a first data line DL1, a second data line DL2, a third data line DL3, and the first data line DL1, the second data line DL2, and the third data line DL3 may be arranged adjacent to the initialization voltage line INL in a state of being adjacent to one another. The first data line DL1, the second data line DL2, and the third data line DL3 may be configured to respectively apply individual data signals to the 1-1 subpixel circuit PC1-1, the 1-2 subpixel circuit PC1-2, and the 1-3 subpixel circuit PC1-3. In addition, the first data line DL1, the second data line DL2, and the third data line DL3 may be configured to respectively apply individual data signals to the 2-1 subpixel circuit PC2-1, the 2-2 subpixel circuit PC2-2, and the 2-3 subpixel circuit PC2-3.

The initialization voltage line INL may be arranged between the first branch line BL1 and the data line DL. In some examples, the initialization voltage line INL may be arranged between the second branch line BL2 and the data line DL. The branch line BL may be arranged opposite the data line DL with reference to the initialization voltage line INL.

The arrangement of the first data line DL1, the second data line DL2, and the third data line DL3, the initialization voltage line INL, and the branch line BL shown in FIG. 5 is only an example, the embodiments of the present disclosure are not limited thereto, and the arrangement may be appropriately modified and corrected according to the design of the subpixel circuits.

The display device 1 may include a structure in which the structure shown in FIG. 5 is repeated in the x direction and the y direction. Accordingly, a plurality of scan lines SL and a plurality of driving voltage lines VDL provided in the display device 1 may form a mesh structure on a plane. Here, the term “on a plane” may indicate “on a virtual plane parallel to a surface of the substrate 100 (see, e.g., FIG. 4) of the display device 1”.

On a plane, a plurality of thin-film transistors (e.g., a first thin-film transistor T1, a second thin-film transistor T2, and a third thin-film transistor T3) and the storage capacitor Cst may be arranged in a space surrounded by the scan lines SL, the driving voltage line VDL, and the initialization voltage line INL adjacent to one another. The plurality of thin-film transistors (i.e., the first thin-film transistor T1, the second thin-film transistor T2, and the third thin-film transistor T3) and the storage capacitor Cst may form a subpixel circuit PC. For example, the 1-1 subpixel circuit PC1-1, the 1-2 subpixel circuit PC1-2, the 1-3 subpixel circuit PC1-3 and the 2-1 subpixel circuit PC2-1, the 2-2 subpixel circuit PC2-2, and the 2-3 subpixel circuit PC2-3 shown in FIG. 5 may each include the first thin-film transistor T1, the second thin-film transistor T2, the third thin-film transistor T3, and the storage capacitor Cst. Hereinafter, for convenience of explanation, a structure and an arrangement of the plurality of thin-film transistors (i.e., the first thin-film transistor T1, the second thin-film transistor T2, and the third thin-film transistor T3) and the storage capacitor Cst provided in the 1-1 subpixel circuit PC1-1 will be mainly described. Except that the 1-2 subpixel circuit PC1-2 and the 1-2 subpixel circuit PC1-2 are respectively connected to a second data line DL2 and a third data line DL3, the 1-2 subpixel circuit PC1-2 and the 1-3 subpixel circuit PC1-3 has a structure and an arrangement identical to or substantially the same as those of the 1-1 subpixel circuit PC1-1 described above. Accordingly, same descriptions of the 1-2 subpixel circuit PC1-2 and the 1-3 subpixel circuit PC1-3 will not be repeated. Likewise, except for the difference in the scan line SL connected to the second subpixel circuit unit PCs2, the second subpixel circuit unit PCs2 has a structure and an arrangement identical to or substantially the same as those of the first subpixel circuit unit PCs1, descriptions of the second subpixel circuit unit PCs2 will not be provided.

Each of the first thin-film transistor T1, the second thin-film transistor T2, and the third thin-film transistor T3 of the 1-1 subpixel circuit PC1-1 may include semiconductor layers (e.g., a first semiconductor layer A1, a second semiconductor layer A2, a third semiconductor layer A3) and gate electrodes (e.g., a first gate electrode G1, a second gate electrode G2, and a third gate electrode G3) overlapping at least a portion of the semiconductor layer (e.g., the first semiconductor layer A1, the second semiconductor layer A2, and the third semiconductor layer A3).

The first thin-film transistor T1 may include the first semiconductor layer A1 and the first gate electrode G1 overlapping at least a portion of the first thin-film transistor T1. The first semiconductor layer A1 may include an oxide semiconductor or a silicon-based semiconductor. The first semiconductor layer A1 may include a channel area, and may also include a source area and a drain area arranged at two sides of the channel area. The source area and the drain area, which have less resistance than the channel area, may be formed through a process of doping impurities or a conduction process. The source area and the drain area may respectively correspond to a source electrode and a drain electrode of a thin-film transistor. Hereinafter, for convenience, the terms “source area” and “drain area” will be used instead of “source electrode” and “drain electrode”. The first gate electrode G1 may overlap a channel area of the first semiconductor layer A1.

Any one of a source area and a drain area of the first semiconductor layer A1 may be electrically connected to the driving voltage line VDL, and another one may be electrically connected to the storage capacitor Cst. For example, the first semiconductor layer A1 may be connected to a fourth connection line CL4 through a first contact hole CNT1, and the fourth connection line CL4 may be electrically connected to the driving voltage line VDL through a tenth contact hole CNT10. In addition, the first semiconductor layer A1 may be electrically connected to the storage capacitor Cst through a second contact hole CNT2. For example, the first semiconductor layer A1 may be connected to a second capacitor plate CE2 of the storage capacitor Cst through the second contact hole CNT2.

The second thin-film transistor T2 may include a second semiconductor layer A2 and a second gate electrode G2 overlapping at least a portion of the second semiconductor layer A2. The second semiconductor layer A2 may include an oxide semiconductor or a silicon-based semiconductor. The second semiconductor layer A2 may include a channel area, and may also include a source area and a drain area arranged at two sides (e.g., opposite sides) of the channel area. The second gate electrode G2 may overlap the channel area of the second semiconductor layer A2. The second gate electrode G2 may correspond to a portion of the first branch line BL1. In other words, the second gate electrode G2 and at least a portion of the first branch line BL1 may be integrally formed (e.g., as a unitary body).

At least any one of the source area and the drain area of the second semiconductor layer A2 may be electrically connected to the storage capacitor Cst, and another one may be electrically connected to the data line DL. For example, the second semiconductor layer A2 may be connected to a first connection line CL1 through a fourth contact hole CNT4, and the first connection line CL1 may be connected to a first capacitor CE1 of the storage capacitor Cst through a third contact hole CNT3. In addition, the second semiconductor layer A2 may be connected to a second connection line CL2 through a fifth contact hole CNT5, and the second connection line CL2 may be connected to a first data line DL1 through a sixth contact hole CNT6.

The third thin-film transistor T3 may include a third semiconductor layer A3 and a third gate electrode G3 overlapping at least a portion of the third semiconductor layer A3. The third semiconductor layer A3 may include an oxide semiconductor or a silicon-based semiconductor. The third semiconductor layer A3 may include a channel area, and may also include a source area and a drain area respectively arranged at two sides of the channel area. The third gate electrode G3 may overlap the channel area of the third semiconductor layer A3. The third gate electrode G3 may correspond to a portion of the first branch line BL1. In other words, the third gate electrode G3 and at least a portion of the first branch line BL1 may be integrally formed (e.g., as a unitary body).

Any one of the source area and the drain area of the third semiconductor layer A3 may be electrically connected to the initialization voltage line INL, and another one may be electrically connected to the storage capacitor Cst. For example, the third semiconductor layer A3 may be connected to a third connection line CL3 through an eighth contact hole CNT8, and the third connection line CL3 may be connected to the initialization voltage line INL through a seventh contact hole CNT7. In addition, the third semiconductor layer A3 may be connected to the second capacitor plate CE2 of the storage capacitor Cst through a ninth contact hole CNT9.

The storage capacitor Cst may include at least two capacitor plates (e.g., electrodes) overlapping each other. For example, the storage capacitor Cst may include the first capacitor plate (e.g., the first capacitor electrode) CE1 and the second capacitor plate (e.g., the second capacitor electrode) CE2 overlapping each other. In some embodiments, the storage capacitor Cst further includes a third capacitor plate CE3 overlapping the first capacitor plate CE1 and the second capacitor plate CE2.

The first capacitor plate CE1 may be integrally formed with the first gate electrode G1. In other words, a portion of the first capacitor plate CE1 may correspond to the first gate electrode G1. In a cross-sectional view, the second capacitor plate CE2 may be disposed on the first capacitor plate CE1 and may correspond to a portion of a node connection line NCL. In other words, the node connection line NCL may include the second capacitor plate CE2. In a cross-sectional view, the third capacitor plate CE3 may be disposed under the first capacitor plate CE1 and may correspond to a portion of a bottom metal layer BML. In other words, the bottom metal layer BML may include a third capacitor plate CE3. The second capacitor plate CE2 may be electrically connected to the third capacitor plate CE3 through an eleventh contact hole CNT11. Here, the term “in a cross-sectional view” may indicate “on a virtual side view parallel to the substrate 100 (see, e.g., FIG. 4) of the display device 1”.

The node connection line NCL may electrically connect the first thin-film transistor T1 and a pixel electrode of the organic light-emitting diode OLED. For example, the node connection line NCL may contact the first thin-film transistor T1 through the second contact hole CNT2, and the pixel electrode 211 (see, e.g., FIG. 4) of the organic light-emitting diode OLED may contact the node connection line NCL through a contact hole and/or a connection electrode. In addition, the node connection line NCL may also be electrically connected to the third thin-film transistor T3. For example, the node connection line NCL may contact the third thin-film transistor T3 through the ninth contact hole CNT9. The node connection line NCL may correspond to the second node N2 shown in FIG. 3A described above.

In some embodiments, the first compensation line IL1 extends in the first direction (e.g., the x direction or the −x direction) from the first branch line BL1 toward the 1-1 subpixel circuit PC1-1 adjacent to the second scan line SL2. The first compensation line IL1 may extend from the first branch line BL1 and may be integrally formed (e.g., as a unitary body)with the first branch line BL1. In other words, the first compensation line IL1 may be arranged at a same layer as the first branch line BL1 and may include the same material as the material of the first branch line BL1. A minimum distance in the second direction (e.g., the y direction or the −y direction) between the second thin-film transistor T2 of the 1-1 subpixel circuit PC1-1 and the second scan line SL2 may be less than a minimum distance in the second direction between the third thin-film transistor T3 of the 1-1 subpixel circuit PC1-1 and the second thin-film transistor T2. In other words, the second thin-film transistor T2 of the 1-1 subpixel circuit PC1-1 may be arranged more adjacent to the second scan line SL2 compared with the third thin-film transistor T3 (e.g., the second thin-film transistor T2 may be positioned closer to the second scan line SL2 than the third thin-film transistor T3). For example, the first compensation line IL1 may be arranged between the second scan line SL2 and the second thin-film transistor T2 to extend in the first direction from the first branch line BL1.

The first scan line SL1 extending in the first direction from a side of the first subpixel circuit unit PCs1 may be configured to provide the scan signal to the first subpixel circuit PC1-1, the second subpixel circuit PC1-2, and the third subpixel circuit PC1-3 of the first subpixel circuit unit PCs1. The first branch line BL1 and the first scan line SL1 may be electrically connected to each other through a twelfth contact hole CNT12. For example, through the first scan line SL1 extending in the second direction (e.g., the y direction or the −y direction), the first scan line SL1 may provide the scan signal to the first subpixel circuit unit PCs1.

In addition, the second scan line SL2 extending in the first direction (e.g., the x direction or the −x direction) from another side of the first subpixel circuit unit PCs1 may be configured to provide the scan signal to the 2-1 subpixel circuit PC2-1, the 2-2 subpixel circuit PC2-2, and the 2-3 subpixel circuit PC2-3 of the second subpixel circuit unit PCs2. The second branch line BL2 and the second scan line SL2 may be electrically connected to each other through a thirteenth contact hole CNT13. For example, through the second branch line BL2 extending in the second direction (e.g. the y direction or the −y direction) from the second scan line SL2, the second scan line SL2 may provide the scan signal to the second subpixel circuit unit PCs2.

When the scan signal is provided to the second subpixel circuit unit PCs2 through the second scan line SL2 and the second branch line BL2, a kickback voltage may be generated at the first gate electrode G1 of the first electrode of the first thin-film transistor T1 of the 2-1 subpixel circuit PC2-1. For example, the kickback voltage may be generated between the first gate electrode G1 of the first electrode of the first thin-film transistor T1 of the 2-1 subpixel circuit PC2-1 and the second scan line SL2 extending in the first direction and adjacent to the first gate electrode G1. In addition, a kickback voltage may be generated between the first gate electrode G1 of the first thin-film transistor T1 of the 2-1 subpixel circuit PC2-1 and the first branch line BL1 extending in the second direction and adjacent to the first gate electrode G1.

When the scan signal is provided to the first subpixel circuit unit PCs1 through the first scan line SL1 and the first branch line BL1, a kickback voltage may also be generated at the first gate electrode G1 of the first thin-film transistor T1 of the 1-1 subpixel circuit PC1-1. For example, the kickback voltage may be generated between the first gate electrode G1 of the first thin-film transistor T1 of the 1-1 subpixel circuit PC1-1 and the first branch line BL1 extending in the second direction (e.g., the y direction or the −y direction) and adjacent to the first gate electrode G1. In addition, a kickback voltage may be generated between the first gate electrode G1 of the first thin-film transistor T1 of the 1-1 subpixel circuit PC1-1 and the first compensation line IL1 extending in the first direction (e.g., the x direction or the −x direction) and adjacent to the first gate electrode G1.

As the first compensation line IL1 is arranged to extend in the first direction from the first branch line BL1, the kickback voltage generated at the first gate electrode G1 of the first thin-film transistor T1 of the 1-1 subpixel circuit PC1-1 and the kickback voltage generated at the first gate electrode G1 of the first thin-film transistor T1 of the 2-1 subpixel circuit PC2-1 may be similar to each other. Light emitted from an organic light-emitting diode electrically connected to the 1-1 subpixel circuit PC1-1 and light emitted from an organic light-emitting diode electrically connected to the 2-1 subpixel circuit PC2-1 may have a same color. As the kickback voltage generated at the first gate electrode G1 of the first thin-film transistor T1 of the 1-1 subpixel circuit PC1-1 and the kickback voltage generated at the first gate electrode G1 of the first thin-film transistor T1 of the 2-1 subpixel circuit PC2-1 are similar to each other, it is possible to prevent or substantially reduce spots due to differences between the kickback voltages of pixels electrically connected to each other and emitting light having a same or substantially the same color.

In some embodiments, the second compensation line IL2 extends in the first direction from the first branch line BL1 toward the 2-3 subpixel circuit PC2-3 adjacent to the first scan line SL1. The second compensation line IL2 may extend from the second branch line BL2 and may be integrally formed (e.g., as a unitary body)with the second branch line BL2. In other words, the second compensation line IL2 may be arranged at a same layer as the second branch line BL2 and may include a same material as a material of the second branch line BL2. A minimum distance in the second direction (e.g., the y direction or the −y direction) between the second thin-film transistor T2 of the 2-3 subpixel circuit PC2-3 and the first scan line SL1 may be less than a minimum distance in the second direction between the third thin-film transistor T3 and the first scan line SL1. In other words, the second thin-film transistor T2 of the 2-3 subpixel circuit PC2-3 may be arranged adjacent to the first scan line SL1 compared with the third thin-film transistor T3. For example, the second compensation line IL2 may be arranged between the first scan line SL1 and the second thin-film transistor T2 to extend in the first direction (e.g., the x direction or the −x direction) from the second branch line BL2.

As described above, the first scan line SL1 and the first branch line BL1 extending from the first scan line SL1 may be configured to provide a scan signal to the first subpixel circuit unit PCs1. When the scan signal is provided to the first subpixel circuit unit PCs1 through the first scan line SL1 and the first branch line BL1, a kickback voltage may be generated at the first gate electrode G1 of the first thin-film transistor T1 of the 1-3 subpixel circuit PC1-3. For example, a kickback voltage may be generated between the first gate electrode G1 of the first thin-film transistor T1 of the 1-3 subpixel circuit PC1-3 and the first scan line SL1 that is adjacent to the first gate electrode G1 and extends in the first direction. In addition, a kickback voltage may be generated between the first gate electrode G1 of the first thin-film transistor T1 of the 1-3 subpixel circuit PC1-3 and the first branch line BL1 that is adjacent to the first gate electrode G1 and extends in the second direction (e.g., the y direction or the −y direction).

When the scan signal is provided to the second subpixel circuit unit PCs2 through the second scan line SL2 and the second branch line BL2, a kickback voltage may also be generated at the first gate electrode G1 of the first thin-film transistor T1 of the 2-3 subpixel circuit PC2-3. For example, the kickback voltage may be generated between the first gate electrode G1 of the first thin-film transistor T1 of the 2-3 subpixel circuit PC2-3 and the second branch line BL2 that is adjacent to the first gate electrode G1 and extends in the second direction. In addition, a kickback voltage may be generated between the first gate electrode G1 of the first thin-film transistor T1 of the 2-3 subpixel circuit PC2-3 and the second compensation line IL2 that is adjacent to the first gate electrode G1 and extends in the first direction (e.g., the x direction or the −x direction).

As the second compensation line IL2 is arranged to extend in the first direction from the second branch line BL2, the kickback voltage generated at the first gate electrode G1 of the first thin-film transistor T1 of the 1-3 subpixel circuit PC1-3 and the kickback voltage generated at the first gate electrode G1 of the first thin-film transistor T1 of the 2-3 subpixel circuit PC2-3 may be similar to each other. Light emitted from an organic light-emitting diode electrically connected to the 1-3 subpixel circuit PC1-3 and light emitted from an organic light-emitting diode electrically connected to the 2-3 subpixel circuit PC2-3 may have a same or substantially the same color. As the kickback voltage generated at the first gate electrode G1 of the first thin-film transistor T1 of the 1-3 subpixel circuit PC1-3 and the kickback voltage generated at the first gate electrode G1 of the first thin-film transistor T1 of the 2-3 subpixel circuit PC2-3 are similar to each other, it is possible to prevent or substantially reduce spots due to differences between the kickback voltages between pixels electrically connected to each other and configured to emit light having a same or substantially the same color.

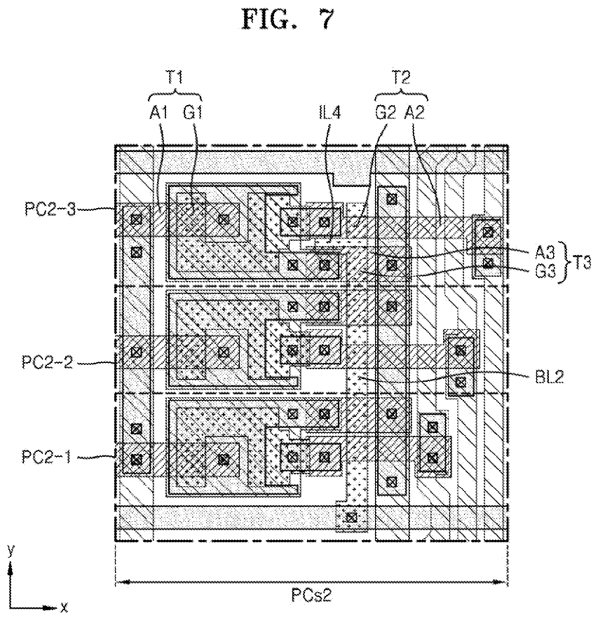

FIGS. 6 and 7 are top-plan views each schematically illustrating the subpixel circuit unit provided in the display device 1 according to some embodiments of the present disclosure. More particularly, FIG. 6 is a top-plan view schematically illustrating the first subpixel circuit unit PCs1 according to some embodiments, and FIG. 7 is a top-plan view schematically illustrating a second subpixel circuit unit PCs2 according to some embodiments.

Referring to FIG. 6, as described above with reference to FIG. 5, the first subpixel circuit unit PCs1 may include the 1-1 subpixel circuit PC1-1, the 1-2 subpixel circuit PC1-2, and the 1-3 subpixel circuit PC1-3. The 1-1 subpixel circuit PC1-1 may be arranged adjacent to the second scan line SL2, and the 1-3 subpixel circuit PC1-3 may be arranged adjacent to the first scan line SL1. The 1-2 subpixel circuit PC1-2 may be arranged between the 1-1 subpixel circuit PC1-1 and the 1-3 subpixel circuit PC1-3.

A minimum distance in the second direction (e.g., the y direction or the −y direction) between the second thin-film transistor T2 of the 1-1 subpixel circuit PC1-1 and the second scan line SL2 may be less than a minimum distance in the second direction between the third thin-film transistor T3 and the second scan line SL2. In other words, the second thin-film transistor T2 of the 1-1 subpixel circuit PC1-1 may be arranged more adjacent to the second scan line SL2 compared with the third thin-film transistor T3 (e.g., the second thin-film transistor T2 may be positioned closer to the second scan line SL2 than the third thin-film transistor T3).

In some embodiments, a third compensation line IL3 extends in the first direction (e.g., the x direction or the −x direction) from the first branch line BL1 toward the 1-1 subpixel circuit PC1-1. In other words, the third compensation line IL3 may be arranged to extend in the first direction between the second thin-film transistor T2 and the third thin-film transistor T3 of the 1-1 subpixel circuit PC1-1. The third compensation line IL3 may be arranged at a same layer as the first branch line BL1 and may include a same material as a material of the first branch line BL1.

When the third compensation line IL3 is arranged between the second thin-film transistor T2 and the third thin-film transistor T3 of the 1-1 subpixel circuit PC1-1, a kickback voltage may be generated at the first gate electrode G1 of the first thin-film transistor T1 of the 1-1 subpixel circuit PC1-1 and the first branch line BL1 that is adjacent to the first gate electrode G1 and extends in the second direction (e.g., the y direction or the −y direction). In addition, a kickback voltage may be generated between the first gate electrode G1 of the first thin-film transistor T1 of the 1-1 subpixel circuit PC1-1 and the third compensation line IL3 that is adjacent to the first gate electrode G1 and extends in the first direction (e.g., the x direction or the −x direction). Accordingly, the kickback voltage generated at the first gate electrode G1 of the first thin-film transistor T1 of the 1-1 subpixel circuit PC1-1 and the kickback voltage generated at the first gate electrode G1 of the first thin-film transistor T1 of the 2-1 subpixel circuit PC2-1 may be similar to each other, and the 1-1 subpixel circuit PC1-1 and the 2-1 subpixel circuit PC2-1 may be electrically connected to pixels configured to emit light having a same or substantially the same color. Therefore, it is possible to prevent or substantially reduce spots caused due to a difference between the kickback voltages of the pixels configured to emit the light having the same color.

Referring to FIG. 7, as described above with reference to FIG. 5, the second subpixel circuit unit PCs2 may include the 2-1 subpixel circuit PC2-1, the 2-2 subpixel circuit PC2-2, and the 2-3 subpixel circuit PC2-3. The 2-1 subpixel circuit PC2-1 may be arranged adjacent to the second scan line SL2, and the 2-3 subpixel circuit PC2-3 may be arranged adjacent to the first scan line SL1. The 2-2 subpixel circuit PC2-2 may be arranged between the 2-1 subpixel circuit PC2-1 and the 2-3 subpixel circuit PC2-3.

The minimum distance in the second direction (e.g., the y direction or the −y direction) between the second thin-film transistor T2 of the 2-3 subpixel circuit PC2-3 and the first scan line SL1 may be less than the minimum distance in the second direction between the third thin-film transistor T3 and the first scan line SL1. In other words, the second thin-film transistor T2 of the 2-3 subpixel circuit PC2-3 may be arranged adjacent to the first scan line SL1 compared with the third thin-film transistor T3.

In some embodiments, a fourth compensation line IL4 extends in the first direction (e.g., the x direction or the −x direction) from the second branch line BL2 toward the 2-3 subpixel circuit PC2-3. In other words, the fourth compensation line IL4 may be arranged between the second thin-film transistor T2 and the third thin-film transistor T3 of the 2-3 subpixel circuit PC2-3 to extend in the first direction. The fourth compensation line IL4 may be arranged at a same layer as the second branch line BL2 and may include a same material as a material of the second branch line BL2.

When the fourth compensation line IL4 is arranged between the second thin-film transistor T2 and the third thin-film transistor T3 of the 2-3 subpixel circuit PC2-3, a kickback voltage may be generated between the first gate electrode G1 of the first thin-film transistor T1 of the 2-3 subpixel circuit PC2-3 and the second branch line BL2 that is adjacent to the first gate electrode G1 and extends in the second direction. In addition, a kickback voltage may be generated between the first gate electrode G1 of the first thin-film transistor T1 of the 2-3 subpixel circuit PC2-3 and the fourth compensation line IL4 adjacent to the first gate electrode G1. Accordingly, the kickback voltage generated at the first gate electrode G1 of the first thin-film transistor T1 and the 2-3 subpixel circuit PC2-3 and the kickback voltage generated at the first gate electrode G1 of the first thin-film transistor T1 of the 1-3 subpixel circuit PC1-3 may be similar to each other, and the 2-3 subpixel circuit PC2-3 and the 1-3 subpixel circuit PC1-3 may be electrically connected to pixels configured to emit light having a same or substantially the same color. Therefore, it is possible to prevent or substantially reduce spots caused do to a difference between the kickback voltages of the pixels configured to emit the light having the same or substantially the same color.

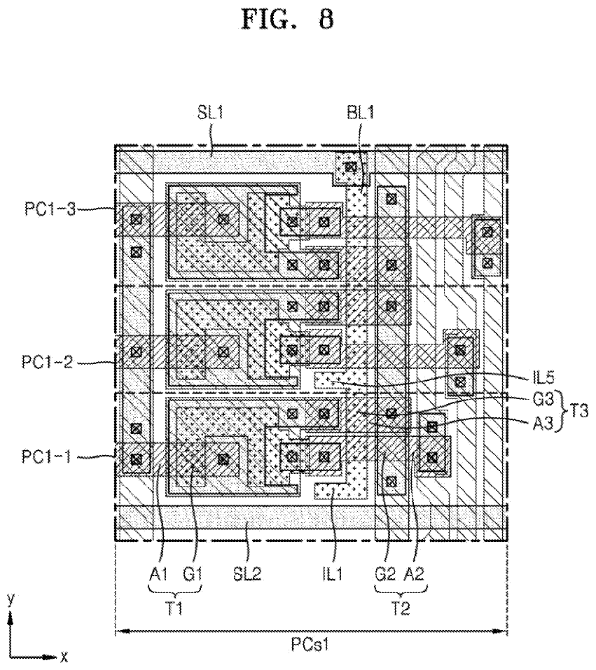

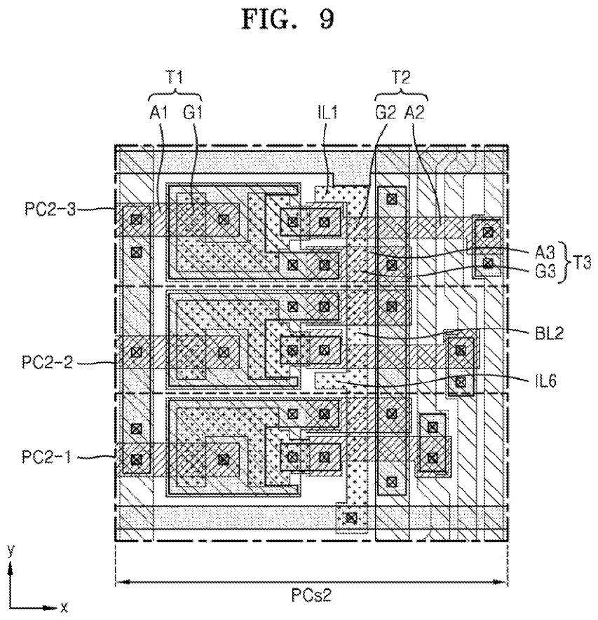

FIGS. 8 and 9 are top-plan views each schematically illustrating the subpixel circuit unit provided in the display device 1 according to some embodiments of the present disclosure. More particularly, FIG. 8 is a top-plan view schematically illustrating the first subpixel circuit unit PCs1 according to some embodiments, and FIG. 9 is a top-plan view schematically illustrating the second subpixel circuit unit PCs2 according to some embodiments.

Referring to FIG. 8, a fifth compensation line IL5 may be arranged to extend in the first direction (e.g., the x direction or the −x direction) from the first branch line BL1 toward the 1-2 subpixel circuit PC1-2. The fifth compensation line IL5 may be arranged at a same layer as the first branch line BL1 and may include a same material as a material of the first branch line BL1. The fifth compensation line IL5 and the first branch line BL1 may be integrally formed (e.g., as a unitary body).

When the scan signal is provided from the first scan line SL1 to the first subpixel circuit unit PCs1, a kickback voltage may also be arranged at the first gate electrode G1 of the first thin-film transistor T1 of the 1-2 subpixel circuit PC1-2. For example, the kickback voltage may be generated between the first gate electrode G1 of the first thin-film transistor T1 of the 1-2 subpixel circuit PC1-2 and the first branch line BL1 that is adjacent to the first gate electrode G1 and extends in the second direction (e.g., the y direction or the −y direction). In addition, a kickback voltage may be generated between the first gate electrode G1 of the first thin-film transistor T1 of the 1-2 subpixel circuit PC1-2 and the fourth compensation line IL4 that is adjacent to the first gate electrode G1 and extends in the first direction (e.g., the x direction or the −x direction). Due to the fourth compensation line IL4 and the first compensation line IL1, the kickback voltages generated at the first gate electrodes G1 of the first thin-film transistors T1 of the 1-1 subpixel circuit PC1-1, the 1-2 subpixel circuit PC1-2, and the 1-3 subpixel circuit PC1-3 may have similar magnitudes.

Referring to FIG. 9, a sixth compensation line IL6 may be arranged to extend in the first direction from the second branch line BL2 toward the 2-2 subpixel circuit PC2-2. The sixth compensation line IL6 may be arranged at a same layer as the second branch line BL2 and may include a same material as a material of the second branch line BL2. The sixth compensation line IL6 and the second branch line BL2 may be integrally formed (e.g., as a unitary body).

When the scan signal is provided from the second scan line SL2 to the second subpixel circuit unit PCs2, a kickback voltage may also be generated at the first gate electrode G1 of the first thin-film transistor T1 of the 2-2 subpixel circuit PC2-2. For example, the kickback voltage may be generated between the first gate electrode G1 of the first thin-film transistor T1 of the 2-2 subpixel circuit PC2-2 and the second branch line BL2 that is adjacent to the first gate electrode G1 and extends in the second direction (e.g., the y direction or the −y direction). In addition, a kickback voltage may be generated between the first gate electrode G1 of the first thin-film transistor T1 of the 2-2 subpixel circuit PC2-2 and the sixth compensation line IL6 that is adjacent to the first gate electrode G1 and extends in the first direction (e.g., the x direction or the −x direction). Due to the sixth compensation line IL6 and the second compensation line IL2, the kickback voltages generated at the first gate electrodes G1 of the first thin-film transistors T1 of the 2-1 subpixel circuit PC2-1, the 2-2 subpixel circuit PC2-2, and the 2-3 subpixel circuit PC2-3 may have similar magnitudes.

In some embodiments, the first compensation line IL1 extends in the first direction from the first branch line BL1 toward the 1-1 subpixel circuit PC1-1 of the first subpixel circuit unit PCs1. A kickback voltage may be generated among the first gate electrode G1 of the first thin-film transistor T1 of the 1-1 subpixel circuit PC1-1, the first branch line BL1 extending in the second direction (e.g., the y direction or the −y direction), and the first branch line BL1 extending in the first direction. In addition, a kickback voltage may also be generated among the first gate electrode G1 of the first thin-film transistor T1 of the 2-1 subpixel circuit PC2-1, the second scan line SL2, and the second branch line BL2 of the second subpixel circuit unit PCs2. As the kickback voltage generated at the first gate electrode G1 of the first thin-film transistor T1 of the 1-1 subpixel circuit PC1-1 and the kickback voltage generated at the first gate electrode G1 of the first thin-film transistor T1 at the 2-1 subpixel circuit PC2-1 have similar magnitudes, when the 1-1 subpixel circuit PC1-1 and the 2-1 subpixel circuit PC2-1 are electrically connected to subpixels configured to emit light having a same or substantially the same color, it is possible to prevent or substantially reduce occurrence of spots due to a difference between the kickback voltages of the pixels configured to emit light having the same or substantially the same color.

In addition, the second compensation line IL2 may extend in the first direction (e.g., the x direction or the −x direction) from the second branch line BL2 toward the 2-3 subpixel circuit PC2-3 of the second subpixel circuit unit PCs2. A kickback voltage may be generated among the first gate electrode G1 of the first thin-film transistor T1 of the 2-3 subpixel circuit PC2-3, the second branch line BL2 extending in the second direction, and the second compensation line IL2 extending in the first direction. In addition, a kickback voltage may also be generated among the first gate electrode G1 of the first thin-film transistor T1 of the 1-3 subpixel circuit PC1-3, the first scan line SL1, and the first branch line BL1 of the first subpixel circuit unit PCs1. As the kickback voltage generated at the first gate electrode G1 of the first electrode of the first thin-film transistor T1 of the 2-3 subpixel circuit PC2-3 and the kickback voltage generated at the first gate electrode G1 of the first thin-film transistor T1 of the 1-3 subpixel circuit PC1-3 have similar magnitudes, when the 2-3 subpixel circuit PC2-3 and the 1-3 subpixel circuit PC1-3 are electrically connected to subpixels configured to emit light having a same color, it is possible to prevent or substantially reduce occurrence of spots due to a difference between the kickback voltages of the pixels configured to emit the light having the same color.

According to the embodiments described above, the display device having improved reliability and quality may be implemented. However, the scope of the embodiments is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a substrate comprising a display area in which display elements are arranged;
a first subpixel circuit unit in the display area and comprising a first subpixel circuit, a second subpixel circuit, and a third subpixel circuit;
a first scan line extending in a first direction from a side of the first subpixel circuit unit;
a second scan line extending in the first direction from another side of the first subpixel circuit unit;
a first branch line extending from the first scan line in a second direction crossing the first direction; and
a first compensation line extending in the first direction from the first branch line toward the first subpixel circuit adjacent to the second scan line.

2. The display device of claim 1, wherein the first subpixel circuit comprises:
a first thin-film transistor in the display area and comprising a first semiconductor layer and a first gate electrode insulated from the first semiconductor layer; and
a second thin-film transistor in the display area and comprising a second semiconductor layer and a second gate electrode insulated from the second semiconductor layer.

3. The display device of claim 2, wherein a minimum distance in the second direction between the first thin-film transistor and the second scan line is less than a minimum distance in the second direction between the second thin-film transistor and the second scan line.

4. The display device of claim 1, wherein the first subpixel circuit is adjacent to the second scan line,
wherein the third subpixel circuit is adjacent to the first scan line, and
wherein the second subpixel circuit is between the first subpixel circuit and the third subpixel circuit.

5. The display device of claim 2, wherein at least a portion of the first branch line is integrally formed in the first gate electrode of the first thin-film transistor.

6. The display device of claim 2, wherein at least a portion of the first branch line is integrally formed in the second gate electrode of the second thin-film transistor.

7. The display device of claim 1, wherein the first compensation line is at a same layer as the first branch line and comprises a same material as a material of the first branch line.

8. The display device of claim 2, wherein the first compensation line is between the second scan line and the first thin-film transistor and extends in the first direction from the first branch line.

9. The display device of claim 3, wherein the first compensation line is between the first thin-film transistor and the second thin-film transistor and extends in the first direction from the first branch line.

10. The display device of claim 1, further comprising a second compensation line extending in the first direction from the first branch line toward the second subpixel circuit.

11. The display device of claim 10, wherein the second compensation line is at a same layer as the first branch line and comprises a same material as a material of the first branch line.

12. A display device comprising:
a substrate comprising a display area in which display elements are arranged;
a second subpixel circuit unit in the display area and comprising a first subpixel circuit, a second subpixel circuit, and a third subpixel circuit;
a first scan line extending in a first direction from a side of the second subpixel circuit unit;
a second scan line extending in the first direction from another side of the second subpixel circuit unit;
a second branch line extending from the second scan line in a second direction crossing the first direction; and
and a third compensation line extending in the first direction from the second branch line toward the third subpixel circuit adjacent to the first scan line.

13. The display device of claim 12, wherein the third subpixel circuit comprises:
a third thin-film transistor in the display area and comprising a third semiconductor layer and a third gate electrode insulated from the third semiconductor layer; and
a fourth thin-film transistor in the display area and comprising a fourth semiconductor layer and a fourth gate electrode insulated from the fourth semiconductor layer.

14. The display device of claim 13, wherein a minimum distance in the second direction between the third thin-film transistor and the first scan line is less than a minimum distance in the second direction between the fourth thin-film transistor and the first scan line.

15. The display device of claim 13, wherein the second branch line is integrally formed in the third gate electrode of the third thin-film transistor.

16. The display device of claim 13, wherein the second branch line is integrally formed in the fourth gate electrode of the fourth thin-film transistor.

17. The display device of claim 13, wherein the third compensation line is at a same layer as the second branch line and comprises a same material as a material of the second branch line.

18. The display device of claim 14, wherein the third compensation line is between the first scan line and the third thin-film transistor and extends in the first direction from the second branch line.

19. The display device of claim 14, wherein the third compensation line is between the third thin-film transistor and the fourth thin-film transistor and extends in the first direction from the second branch line.

20. The display device of claim 12, further comprising a fourth compensation line extending in the first direction from the second branch line toward the second subpixel circuit.
